(19) United States
(12) Patent Application Publication
(10) Pub. No.: US 2009/0009257 A1
(43) Pub. Date: Jan. 8, 2009

(54) Varactor Trimming Arrangement

(75) Inventors: Anders Emericks, Solna (SE); Lars Karlsson, Taby (SE)

Correspondence Address: LEE & HAYES, PLLC, 601 W RIVERSIDE, SUITE 1400, SPOKANE, WA, 99201, US

(73) Assignee: Infineon Technologies AG, Neubiberg (DE)

(21) Appl. No.: 11/774,414

(22) Filed: Jul. 6, 2007

(51) Int. Cl. H03B 5/08

(52) U.S. Cl. 331/177 V; 331/167

(57) ABSTRACT

Implementations are presented herein that relate to circuit arrangements that employ the use of a varactor.

### BACKGROUND

Voltage controlled oscillators (VCOs) are used in many systems, such as communications systems and computers. These systems often employ the use of frequencies that need to be synthesized. Frequency synthesis may be used, for example, to provide a carrier frequency for a signal in a communications system.

VCOs are configured to have an oscillation, or resonant, frequency. For oscillation frequencies higher than about 1 GHz, typically LC (inductance/capacitance) oscillators are used because they have low noise and are relatively stable. LC oscillators typically use a tank circuit including an inductance (L) and a capacitance (C) connected in series or in parallel to provide a resonance circuit. The oscillation frequency of the LC tank depends on a product of the inductance and capacitance (the LC product) of the tank.

A control voltage called the tuning voltage may be used in a VCO to adjust the oscillation frequency. The oscillation frequency can also be adjusted by varying the capacitance of the tank using a tuning voltage. This may be accomplished by implementing the tank capacitor as a varactor, whose capacitance varies with the tuning voltage. The tuning voltage has a range of voltages that can be provided, corresponding to a range of capacitances that can be provided. This range of capacitances corresponds to a range of frequencies producible by the LC tank. The varactor is typically designed to have a desired nominal capacitance, so that the LC tank will oscillate at a desired frequency, when the tuning voltage is at a nominal voltage. The nominal voltage will be approximately in the middle of the tuning voltage range if the change in oscillation frequency is linear relative to the change in the tuning voltage.

FIG. 1 illustrates a conventional VCO 100 incorporating digitally controlled capacitor 102 that may be used to align the capacitance of the VCO core. Note, the conventional VCO 100 illustrated in FIG. 1 is shown in single ended configuration. The VCO 100 may include an inductor 104 coupled to a varactor 106. The digitally controlled capacitor 102 has one end coupled between the inductor 104 and the varactor 106.

The varactor 106 of the VCO 100 implementation illustrated in FIG. 1 has a capacitive range

$$\frac{{C}_{max} - {C}_{min}}{V} ,$$

where Cₘᵢₙ and Cₘₐₓ are the capacitance limits of the varactor 106 and assuming the voltage difference for Cₘₐₓ-Cₘᵢₙ is 1 volt. The total capacitance (Cₜₒₜₐₗ) of the VCO 100 is the capacitance of the digitally controlled capacitor 102 summed with the varactor 106. The frequency at various capacitance levels of the varactor 106 is represented by

$$f = \frac{\sqrt{( \frac{1}{L * {C}_{total}} )}}{2 π} ,$$

where Cₜₒₜₐₗ is the total capacitance of the VCO 100 and L is the inductance of the inductor 104.

The gain (K_{VCO}) of the VCO 100 may be expressed as

$$\frac{Hz}{V} .$$

In some applications, it is desirable to maintain a nearly constant VCO gain over a capacitance range of the varactor 106. The capacitance range of the varactor 106 may be expressed as Cₘᵢₙ and Cₘₐₓ. However, as the digitally controlled capacitor 102 is changed to enable the VCO frequency to switch frequency bands, the varactor 106 capacitance values within the range of Cₘᵢₙ and Cₘₐₓ prevent the gain of the VCO 100 from remaining substantially constant over an operating range thereof. This makes the conventional VCO 100 unsuitable for some applications.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical items.

FIG. 1 is a circuit diagram of a conventional voltage controlled oscillator (VCO), which is shown as a single ended model.

FIG. 2 is a circuit diagram of a VCO, shown as a single ended model, according to one exemplary implementation. The illustrated VCO employs the use of a plurality of switched capacitors to substantially assure a stable VCO gain over a frequency range thereof.

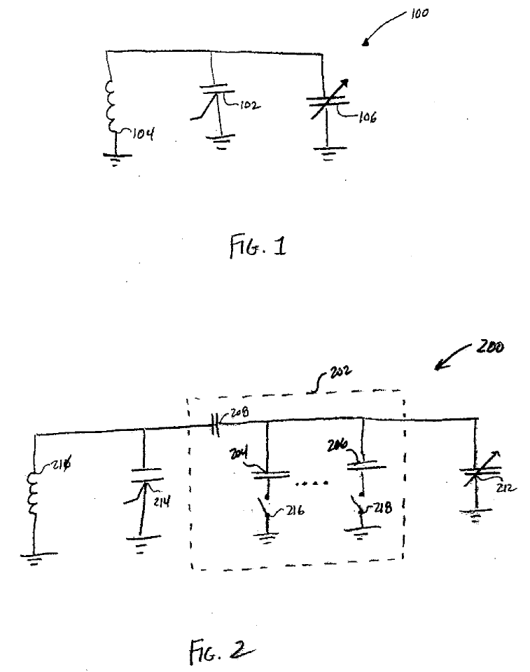

### DETAILED DESCRIPTION

### Overview

According to an implementation described herein, a voltage controlled oscillator (VCO) includes an LC (inductance-capacitance) tank that uses an inductor and a varactor. To maintain a substantially stable VCO gain over a capacitance range of the varactor, a trimming block is interposed between a digitally controlled capacitor and the varactor of the VCO. The trimming block may employ a plurality of switched capacitors that are enabled and/or disabled to help maintain a substantially constant VCO gain even as capacitances of the digitally controlled capacitor and the varactor change.

### Exemplary Arrangements

FIG. 2 is a circuit diagram of a VCO 200 according to one exemplary implementation. The illustrated VCO 200 employs the use of a trimming block 202 that includes a plurality of switched capacitors 204 and 206 in parallel with a varactor 212 of an LC tank. A switch 216 is associated with the capacitor 204 and a switch 218 is associated with the capacitor 206. The trimming block 202 also includes a capacitor 208. The trimming block 202 is designed to substantially assure a stable VCO 200 gain (K_{VCO}) over a frequency range of the LC tank. The digitally controlled capacitor 214 may be used to align the the core frequency of the VCO 200.

A total capacitance (Cₜₒₜₐₗ) of the VCO 200 can be expressed by the equation:

Cₜₒₜₐₗ=C₂₁₄+C₂₀₈//(C₂₀₄*SW₂₁₆+C₂₀₆*SW₂₁₈+C₂₁₂)

Toggling the switches, using a control device (not illustrated), enables a substantially stable VCO 200 gain, independent of a capacitance values of the digitally controlled capacitor 214 and the varactor 212. From the FIG. 2 it can be seen that if the switches 216 and 218 are set, the capacitances 204 and 206 are coupled in parallel with the varactor 212. The capacitor 208 will be coupled in series to the sum of the parallel capacitances 212, 204 and 206. By this arrangement, the total capacitance variance of the varactor 212 plus the trimming block 202 may be matched to the follow the value of the digitally controlled capacitor 214.

With the switches 216 and 218 open, the capacitance of the VCO 200 equals the capacitor 208 in series with the varactor 212, including the capacitance of the digitally controlled capacitor 214. The capacitor 208 is used to isolate the varactor 212 from the digitally controlled capacitor 214. Therefore, the influence of the varactor 212 on the VCO 200 is affected by the inclusion of the capacitor 208.

Changing the capacitance value of the varactor 212 enables the production of various frequencies. When enabled or switched on, the capacitors 204 and/or 206 are in parallel with the varactor 212. The capacitors 204 and 206 are generally used to lower or negate the influence that the varactor 212 has on the total capacitance of the VCO 200.

In general, when the digitally controlled capacitor 214 is at a low capacitance level (e.g. ˜400 fF) both the switches 216 and 218 are enabled to decrease the influence of the varactor 212. When the digitally controlled capacitor 214 is at a low-mid capacitance level (e.g. ˜500 fF) only one of the switches 216 or 218 is enabled. Which switch (216 or 218) is enabled depends on which of the capacitors (204 or 206) is smaller. When the digitally controlled capacitor 214 is at a mid-high capacitance level (e.g. ˜600 fF) only one of the switches 216 or 218 is enabled. Which switch (216 or 218) is enabled depends on which of the capacitors (204 or 206) is larger. And when the digitally controlled capacitor 214 is at a high capacitance level (e.g. ˜750 fF) none of the switches 216 and 218 is enabled.

Depending on the state of the switches 216 and 218, capacitance may be added to the VCO 200 to compensate for the capacitance levels of the digitally controlled capacitor 214 and the varactor 212. The switches 216 and/or 218 are enabled to add capacitance to the VCO 200 when the digitally controlled capacitor 214 is at a low capacitance range; and the switches 216 and/or 218 are disabled when the digitally controlled capacitor 214 is at a high capacitance range. Therefore, as the digitally controlled capacitor 214 is varied to align the frequency of the VCO 200, in conjunction with the varying of the varactor 212 to achieve a certain frequency response characteristics, the gain of the VCO 200 is maintained at substantially constant level.

The following data illustrates the performance of the VCO 200 with a given set of valued components. In this example, the capacitor 204 has a value of 75 fF, the capacitor 206 has a value of 150 fF, the capacitor 208 has a value of 750 fF, and the varactor 212 has a low capacitance of 80 fF and a high capacitance of 120 fF. As those skilled in the art appreciate, when switches 216 and 218 are enabled, the associated capacitors 216 and 218 add capacitance to the VCO 200 and lower the impact of the varactor 212. When the switches 216 and 218 are not enabled, the associated capacitors 216 and 218 do not add capacitance to the VCO 200.

TABLE I

| | Cₜₒₜₐₗ @ | Cₜₒₜₐₗ @ | ΔF | K_{vco} | | | |
|---|---|---|---|---|---|---|---|
| C₂₁₄(fF) | C₂₁₂ Low(fF) | C₂₁₂ High(fF) | $( \frac{fF}{V} )$ | $( \frac{MHz}{V} )$ | SW216 | SW218 | C₂₀₄ +C₂₀₆ |
| 420 | 637 | 656 | 19.5 | 60 | ON | ON | 225 |
| 535 | 711 | 734 | 22.5 | 58 | ON | OFF | 150 |
| 650 | 779 | 805 | 26.3 | 60 | OFF | ON | 75 |
| 765 | 837 | 868 | 31.2 | 63 | OFF | OFF | 0 |

The data of TABLE I shows that adding capacitance to the VCO 200, by way of enabling one or more of the switches 216 and/or 218, allows the gain of the VCO 200 to remain substantially constant. The data provided in TABLE 1 shows that when the digitally controlled capacitor 214 is at a low capacitance level (e.g., 420 fF), the change in frequency is 19.5 and the VCO 200 gain (K_{VCO}) is at 60. At the capacitance high end (e.g., 765 fF) of the digitally controlled capacitor 214, the change in frequency is 31.2 and the VCO 200 gain (K_{VCO}) is at 63. This data shows that the arrangement illustrated in FIG. 2 achieves a substantially stable VCO 200 gain (K_{VCO}) over a frequency range of the LC tank.

The circuit arrangement illustrated in FIG. 2 may be implemented as a unitary integrated circuit and/or as several integrated circuits that function together. Such integrated circuit(s) may be used in conjunction with communications systems and devices.

### Conclusion

For the purposes of this disclosure and the claims that follow, the terms “coupled” and “connected” have been used to describe how various elements interface. Such described interfacing of various elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as example forms of implementing the claims.

What is claimed is:

1. A circuit arrangement, comprising:
an inductor;
a controllable capacitor coupled to the inductor; and
a varactor coupled to a trimming block,
wherein the trimming block is coupled between the controllable capacitor and the varactor, the trimming block including a serial capacitor coupled between the controllable capacitor and a plurality of switched capacitors that are coupled to the varactor, the trimming block operable to change capacitance as a capacitance value of the controllable capacitor varies.

2. The circuit arrangement according to claim 1, wherein the plurality of switched capacitors are a first capacitor in parallel with a second capacitor.

3. The circuit arrangement according to claim 1, wherein the plurality of switched capacitors are a first capacitor in parallel with a second capacitor, each of the first and second capacitor including a switch that may be switched as a capacitance value of the controllable capacitor changes.

4. The circuit arrangement according to claim 1, wherein the circuit arrangement is a voltage controlled oscillator (VCO).

5. The circuit arrangement according to claim 1, wherein the circuit arrangement is integrated on an integrated circuit.

6. The circuit arrangement according to claim 1, wherein the circuit arrangement is integrated on a plurality of integrated circuits.

7. The circuit arrangement according to claim 1, further comprising a controller to control the switched capacitors.

8. The circuit arrangement according to claim 7, wherein the controller enables or disables the switched capacitors depending on a capacitance value of the controllable capacitor.

9. The circuit arrangement according to claim 1, wherein the serial capacitor isolates the varactor from form the controllable capacitor.

10. The circuit arrangement according to claim 1, wherein each of the switched capacitors is in parallel with the varactor when switched on.

11. The circuit arrangement according to claim 1, wherein the plurality of switched capacitors are coupled in parallel with the varactor.

12. A method, comprising:
providing an inductor;
coupling a controllable capacitor to the inductor; and
coupling a varactor to a trimming block,
wherein the trimming block is coupled between the controllable capacitor and the varactor, the trimming block including a serial capacitor coupled between the controllable capacitor and a plurality of switched capacitors that are coupled to the varactor, the trimming block operable to change capacitance as a capacitance value of the controllable capacitor varies.

13. The method according to claim 12, further comprising isolating the varactor from the controllable capacitor by way of the serial capacitor.

14. The method according to claim 12, further comprising substantially matching a capacitance value of the varactor and the trimming block to a capacitance value of the controllable capacitor.

15. The method according to claim 12, further comprising using a control device to enable the switched capacitors.

16. The method according to claim 12, further comprising arranging the switched capacitors in parallel with the varactor.
